(19) United States
(12) Patent Application Publication
(10) Pub. No.: US 2012/0068154 A1
(43) Pub. Date: Mar. 22, 2012

(54) GRAPHENE QUANTUM DOT LIGHT EMITTING DEVICE AND METHOD OF MANUFACTURING THE SAME

(75) Inventors: Sung-won HWANG, Suwon-si (KR); Geun-woo KO, Suwon-si (KR); Sung-hyun SIM, Seoul (KR); Hun-jae CHUNG, Suwon-si (KR); Cheol-soo SONE, Seoul (KR); Jin-hyun LEE, Suwon-si (KR); Byung-hee HONG, Suwon-si (KR); Su-kang BAE, Suwon-si (KR)

(73) Assignee: SAMSUNG LED CO., LTD., Suwon-si (KR)

(21) Appl. No.: 13/234,620

(22) Filed: Sep. 16, 2011

(30) Foreign Application Priority Data
Sep. 16, 2010 (KR) 10-2010-0091282
Sep. 9, 2011 (KR) 10-2011-0092235

(51) Int. Cl. H01L 51/54; H01L 51/56

(52) U.S. Cl. 257/13; 438/47; 257/E51.026

(57) ABSTRACT

A graphene quantum dot light emitting device includes: a first graphene; a graphene quantum dot layer disposed on the first graphene and including a plurality of graphene quantum dots; and a second graphene disposed on the graphene quantum dot layer. A method of manufacturing a graphene quantum dot light emitting device includes: forming a first graphene doped with a first dopant; forming a graphene quantum dot layer including a plurality of graphene quantum dots on the first graphene; and forming a second graphene doped with a second dopant on the graphene quantum dot layer.

### CROSS-REFERENCE TO RELATED PATENT APPLICATION

This application claims the benefit of Korean Patent Application Nos. 10-2010-0091282, filed on Sep. 16, 2010 and 10-2011-0092235, filed on Sep. 9, 2011, in the Korean Intellectual Property Office, the disclosure of which is incorporated herein in its entirety by reference.

### BACKGROUND OF THE INVENTION

1. Field of the Invention

The present invention relates to a graphene quantum dot light emitting device and a method of manufacturing the graphene quantum dot light emitting device.

2. Description of the Related Art

A quantum dot electroluminescence device (QD-EL) is a device basically having a three-layered structure including a hole transport layer (HTL), an electron transport layer (ETL), and a QD light emitting layer disposed between the HTL and the ETL.

A quantum dot is a semiconductor material having a crystalline structure of a few nm size, and includes hundreds to thousands atoms. Since the quantum dot has a very small size, a surface area per unit volume is large, most of atoms exist on surfaces of nano-crystals, and a quantum confinement effect is shown. Due to the quantum confinement effect, a wavelength of emitted light may be adjusted by controlling the size of the quantume dots, and excellent color purity and high photoluminescence (PL) efficiency may be obtained.

However, light emitting efficiency of the QD-EL device is degraded due to a low compatibility with an organic material used as the ETL and the HTL and lack of semiconductor nano-particles of high efficiency. Therefore, researches on the QD-EL device for improving the efficiency are being actively conducted.

### SUMMARY OF THE INVENTION

According to an aspect of the present invention, there is provided a graphene quantum dot light emitting device including: a first graphene; a graphene quantum dot layer disposed on the first graphene and including a plurality of graphene quantum dots; and a second graphene disposed on the graphene quantum dot layer.

The first graphene may be an n-type graphene, and the second graphene may be a p-type graphene.

The graphene quantum dot light emitting device may further include an electron transport layer (ETL) disposed between the n-type graphene and the graphene quantum dot layer.

The ETL may include TPBi(1,3,5-tris(N-phenylbenzimidazol-2,yl)benzene), PBD(2-(4-Biphenylyl)-5-(4-tert-butylphenyl)-1,3,4-oxadiazole), BCP(2,9-Dimethyl-4,7-diphenyl-1,10-phenanhro-line), BAlq(Bis-(2-methyl-8-quinolinolate)-4-(phenylphenolato)aluminium), or OXD7(1,3-bis(N,N-t-butyl-phenyl)-1,3,4-oxadiazole).

The graphene quantum dot light emitting device may further include a hole transport layer (HTL) between the graphene quantum dot layer and the p-type graphene. The HTL may include poly-TPD(N,N′-bis(3-methylphenyl)-N,N′-bis(phenyl)-benzidine), PEDOT(poly(3,4-ethylenedioxythiophene)), PSS(poly(styrenesulfonate)), PPV(poly(p-phenylene vinylene)), PVK(poly(N-vinylcarbazole)), TFB(poly[(9,9-dioctylfluorenyl-2,7-diyl)-co-(4,4′(N-(4-sec-butylphenyl)))diphenylamine], PFB, TBADN(3-Tert-butyl-9,10-di(naphth-2-yl)anthracene), NPB(N,N′-bis(1-naphtalenyl)-N-N′-bis(phenyl-benzidine)), Spiro-NPB(N,N′-di(naphthalen-1-yl)-N,N′-diphenyl-spiro), DMFL-NPB(N,N′-di(naphthalene-1-yl)-N,N′-diphenyl-9,9′-dimethyl-fluorene), DPFL-NPB(N,N′-di(naphthalen-1-yl)-N,N′-diphenyl-9,9′-diphenyl-fluorene), or mHOST5(2,7-Di(N,N′-carbarzolyl)-9,9-bis[4-(2-ethylhexyloxy)-phenyl]fluorine).

The graphene quantum dot layer may further include an organic solvent.

The plurality of graphene quantum dots may have a size of about 1 nm to about 30 nm.

The n-type graphene may be doped with one of selected from nitrogen (N), fluorine (F), and manganese (Mn).

The p-type graphene may be doped with one of selected from oxygen (O), gold (Au), and bismuth (Bi).

The graphene quantum dot light emitting device may further include a first contact pad that is disposed on the first graphene to be separated from the graphene quantum dot layer and the second graphene, or on a lower surface of the first graphene.

The graphene quantum dot light emitting device may further include a second contact pad disposed on the second graphene.

According to another aspect of the present invention, there is provided a method of manufacturing a graphene quantum dot light emitting device, the method including: forming a first graphene doped with a first dopant; forming a graphene quantum dot layer including a plurality of graphene quantum dots on the first graphene; and forming a second graphene doped with a second dopant on the graphene quantum dot layer.

The first dopant may be an n-type dopant, and the second dopant may be a p-type dopant.

The n-type dopant may be one of selected from nitrogen (N), fluorine (F), and manganese (Mn).

The p-type dopant may be one of selected from oxygen (O), gold (Au), and bismuth (Bi).

The method may further include forming an electron transport layer (ETL) between the first graphene and the graphene quantum dot layer.

The ETL may include TPBi(1,3,5-tris(N-phenylbenzimidazol-2,yl)benzene), PBD(2-(4-Biphenylyl)-5-(4-tert-butylphenyl)-1,3,4-oxadiazole), BCP(2,9-Dimethyl-4,7-diphenyl-1,10-phenanhro-line), BAlq(Bis-(2-methyl-8-quinolinolate)-4-(phenylphenolato)aluminium), or OXD7(1,3-bis(N,N-t-butyl-phenyl)-1,3,4-oxadiazole).

The method may further include forming a hole transport layer (HTL) between the graphene quantum dot layer and the second graphene.

The HTL may include poly-TPD(N,N′-bis(3-methylphenyl)-N,N′-bis(phenyl)-benzidine), PEDOT(poly(3,4-ethylenedioxythiophene)), PSS(poly(styrenesulfonate)), PPV(poly(p-phenylene vinylene)), PVK(poly(N-vinylcarbazole)), TFB(poly[(9,9-dioctylfluorenyl-2,7-diyl)-co-(4,4′(N-(4-sec-butylphenyl)))diphenylamine]), PFB, TBADN(3-Tert-butyl-9,10-di(naphth-2-yl)anthracene), NPB(N,N′-bis(1-naphtalenyl)-N-N′-bis(phenyl-benzidine)), Spiro-NPB(N,N′-di(naphthalen-1-yl)-N,N′-diphenyl-spiro), DMFL-NPB(N,N′-di(naphthalene-1-yl)-N,N′-diphenyl-9,9′-dimethyl-fluorene), DPFL-NPB(N,N′-di(naphthalen-1-yl)-N,N′-diphenyl-9,9′-diphenyl-fluorene), or mHOST5(2,7-Di(N,N′-carbarzolyl)-9,9-bis[4-(2-ethylhexyloxy)-phenyl]fluorine).

The plurality of graphene quantum dots may be formed by applying ultrasonic waves to a solution including graphite, and breaking the graphite.

The plurality of graphene quantum dots may be formed by heating graphite oxide to reduce a part of the graphite oxide, and cutting the reduced part of the graphite oxide.

The graphene quantum dot layer may be formed by spin coating the plurality of graphene quantum dots on the first graphene.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a graphene quantum dot light emitting device according to an embodiment of the present invention;

FIG. 2 is a plan view showing a plurality of graphene quantum dots disposed on a first graphene;

FIG. 3 is a plan view showing a plurality of graphene quantum dots regularly arranged on the first graphene;

FIG. 4 is a plan view showing a plurality of graphene quantum dots regularly arranged on the first graphene;

FIGS. 5A through 5C are plan views exemplary showing shapes of graphene quantum dots;

FIG. 6 is a schematic cross-sectional view of a graphene quantum dot light emitting device according to another embodiment of the present invention;

FIG. 7 is a graph showing an example of an energy band structure of the graphene quantum dot light emitting device of FIG. 6;

FIGS. 8A through 8D are graphs schematically showing light emitting characteristics of the graphene quantum dot light emitting device of FIG. 6;

FIGS. 9A through 9F are cross-sectional views illustrating processes of manufacturing a graphene quantum dot light emitting device according to an embodiment of the present invention;

FIGS. 10A through 10D are cross-sectional views illustrating processes of manufacturing a graphene quantum dot light emitting device according to another embodiment of the present invention;

FIGS. 11A through 11D are graphs schematically showing light emitting characteristics of graphene quantum dot light emitting devices according to embodiments of the present invention;

FIGS. 12A through 12D are graphs schematically showing light emitting characteristics of graphene quantum dot light emitting devices according to embodiments of the present invention.

### DETAILED DESCRIPTION OF THE INVENTION

Various example embodiments will now be described more fully with reference to the accompanying drawings in which some example embodiments are shown.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element or layer is referred to as being “formed on,” another element or layer, it can be directly or indirectly formed on the other element or layer. That is, for example, intervening elements or layers may be present.

In contrast, when an element or layer is referred to as being “directly formed on,” to another element, there are no intervening elements or layers present. Other words used to describe the relationship between elements or layers should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the thicknesses of layers and regions are exaggerated for clarity. Like reference numerals in the drawings denote like elements.

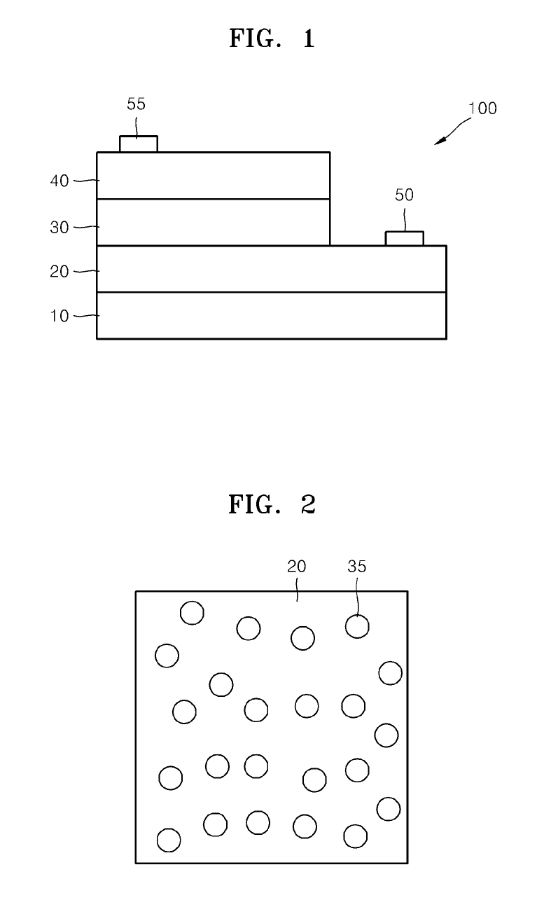

FIG. 1 is a schematic cross-sectional view of a graphene quantum dot light emitting device 100 according to an embodiment of the present invention.

Referring to FIG. 1, the graphene quantum dot light emitting device 100 includes a substrate 10, a first graphene 20 disposed on the substrate 10, a graphene quantum dot layer 30 disposed on the first graphene 20, and a second graphene 40 disposed on the graphene quantum dot layer 30. In addition, the graphene quantum dot light emitting device 100 of the present embodiment may further include a first contact pad 50 that is disposed on an exposed region of the first graphene 20 to be separated from the graphene quantum dot layer 30 and the second graphene 40. In addition, the graphene quantum dot light emitting device 100 of the present embodiment may further include a second contact pad 55 disposed on the second graphene 40.

The substrate 10 may be formed of glass, sapphire, polyethylene terephthalate (PET), Si, ZnO, GaAs, SiC, MgAl₂O₄, MgO, LiAlO₂, LiGaO₂ , or GaN. The substrate 10 may be removed after the first graphene 20, the graphene quantum dot layer 30, and the second graphene 40 are formed on the substrate 20. On the other hand, in the graphene quantum dot light emitting device 100 of the present embodiment, the first graphene 20 may function as a substrate without including an additional substrate 10.

The first graphene 20 is disposed on the substrate 10. The graphene is a conductive material in which carbon atoms are arranged as a two-dimensional honeycomb shape having a thickness of a layer of atoms. The graphene is stabilized structurally and chemically, and is an excellent conductive material having a charge mobility that is faster than that of silicon. In addition, more electric current may flow on the graphene than copper. In addition, the graphene has a transparency that is higher than that of indium tin oxide (ITO) that is conventionally used as a transparent electrode. The graphene that is not doped with a dopant does not have an energy band gap since a valence band and a conduction band meet each other. However, when an n-type dopant or a p-type dopant is doped on the graphene, energy band gap is generated. The energy band gap may be adjusted according to a kind of the dopant, and doping density.

Here, the first graphene 20 may be n-type graphene. That is, the first graphene 20 may be used as an n-type electrode or an electron transport layer (ETL). The n-type graphene 20 is formed by doping at least one graphene sheet with the n-type dopant. The graphene sheet may be formed on the substrate 10 in a chemical vapor deposition (CVD) method, a mechanical or chemical removal method, or an epitaxy growth method. On the other hand, the graphene sheet may be transferred onto the substrate 10 after being formed on an auxiliary substrate that is formed of polydimethylsiloxane (PDMS). In addition, the n-type dopant is injected and adsorbed on the graphene sheet to form the n-type graphene 20. The n-type dopant may be, for example, nitrogen (N), fluorine (F), or manganese (Mn); however, the present invention is not limited thereto. The first graphene 20 may have a thickness of about 0.34 nm, and when the first graphene 20 has a structure in which a plurality of graphene sheets are stacked, the thickness of the first graphene 20 may be an interger multiple of about 0.34 nm. Since the thickness of the first graphene 20 is less than a wavelength of light emitted from the graphene quantum dot layer 30, a total reflection may not occur on an interface between the two layers 20 and 30.

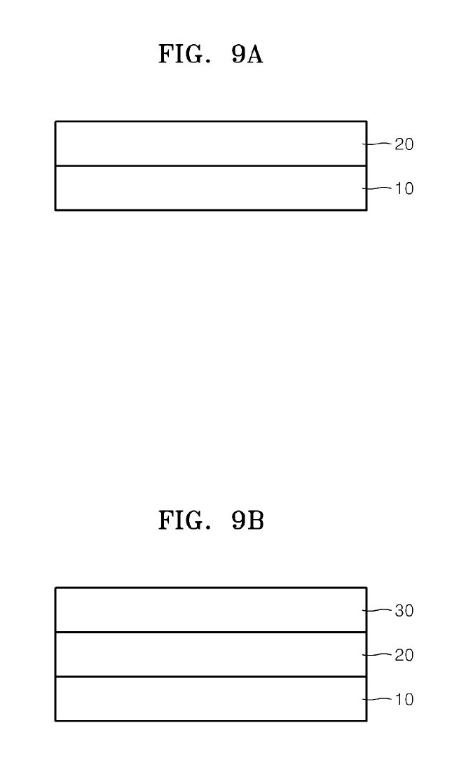

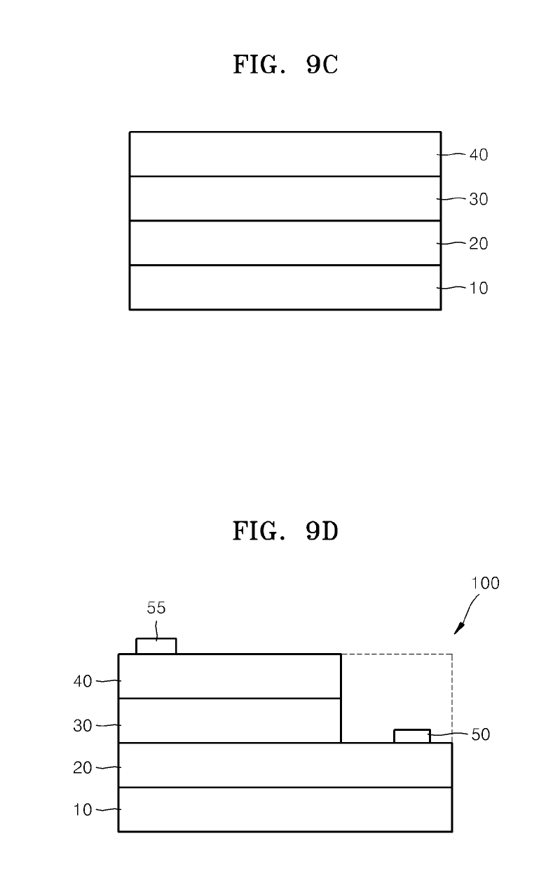

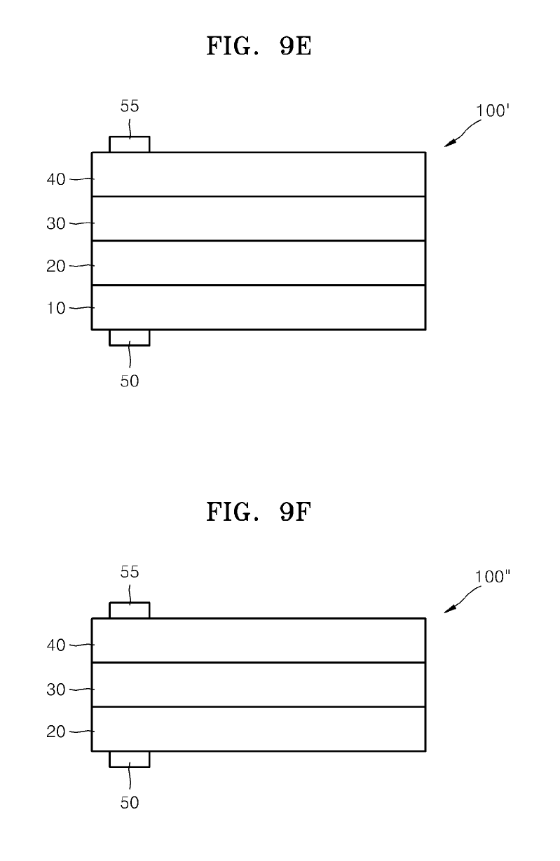

Since the first graphene 20 has high electric conductivity, an additional first electrode may not be formed. However, the first contact pad 50 may be disposed on the first graphene 20 to be separated from the graphene quantum dot layer 30 and the second graphene 40. That is, in a mesa-structure in which a part of the first graphene 20 is exposed due to a mesa-etching of the graphene quantum dot layer 30 and the second graphene 40, the first contact pad 50 is disposed on the exposed part of the first graphene 20. On the other hand, as shown in FIG. 9E, the first contact pad 50 may be formed on a lower surface of the substrate 10, that is, a surface opposite to the surface there the first graphene 20 is formed, when the substrate 10 is the conductive substrate. Otherwise, as shown in FIG. 9F, the first contact pad 50 may be formed on a lower surface of the first graphene 20, that is, a surface opposite to the surface where the graphene quantum dot layer 30 is formed of the first graphene 20, after removing the substrate 10. In addition, the first contact pad 50 may inject electrons into the first graphene 20.

The graphene quantum dot layer 30 may be disposed on the first graphene 20, and may emit light having a predetermined energy by recombining electrons and holes. The graphene quantum dot layer 30 may include a plurality of graphene quantum dots, and the plurality of graphene quantum dots may be arranged on the first graphene 20 in various shapes, which will be described with reference to FIGS. 2 through 4.

The graphene quantum dot may be a graphene nano-particle having a size of about 1 nm to about 30 nm, or about 1 nm to about 20 nm, in more detail, about 1 nm to about 10 nm. In addition, a functional group may be further coupled to a surface or an edge of the graphene quantum dot. Amine-based functional group may be attached to the graphene quantum dot, for example, alkylamines, aniline, or polyethylene glycol (PEG). Although the graphene quantum dot has a lot of electrons therein, the number of free electrons may be limited in a range from about 1 to about 100. In this case, the graphene quantum dot may represent electrical and optical characteristics that are different from those of sheet type graphene, in which a continuous band is formed by discontinuously limiting energy levels of the electrons. Since the energy level of the graphene quantum dot varies depending on a size and a shape thereof, the band gap may be adjusted by changing the size and the shape of the graphene quantum dot. That is, a wavelength of the emitted light may be adjusted by adjusting the size and shape of the graphene quantum dot. In addition, density of states of the electrons and holes at the bandgap edge of the graphene quantum dot is much higher than that of the graphene sheet, combinations of the excited electrons and holes are increased and the light emitting efficiency may be improved.

The second graphene 40 may be disposed on the graphene quantum dot layer 30. Here, the second graphene 40 may a p-type graphene. That is, the second graphene 40 may be used as a p-type electrode or a hole transport layer (HTL). The p-type graphene 40 is formed by doping at least one graphene sheet with the p-type dopant. The graphene sheet may be formed in a CVD method, a mechanical or chemical removal method, or an epitaxy growth method. In addition, the p-type dopant is injected and adsorbed on the graphene sheet to form the p-type graphene 40. The p-type dopant may be, for example, oxygen (O), gold (Au), or bismuth (Bi); however, the present invention is not limited thereto. On the other hand, the second graphene 40 may have a thickness of about 0.34 nm, and if the second graphene 40 has a structure in which a plurality of graphene sheets are stacked, the thickness of the second graphene 40 may be an integer multiple of about 0.34 nm. Since the thickness of the second graphene 40 is less than a wavelength of light emitted from the graphene quantum dot layer 30, a total reflection may not occur on an interface between the two layers 30 and 40.

Since the second graphene 40 has high electric conductivity, an additional second electrode may not be formed. However, the second contact pad 55 may be disposed on the second graphene 40. The second contact pad 55 may inject holes in the second graphene 40. In the above description, the first and second graphenes 20 and 40 are respectively the n-type and p-type graphenes; however, the first and second graphenes 20 and 40 may be respectively p-type and n-type graphenes. According to the graphene quantum dot light emitting device 100 of the present embodiment, the light emitting efficiency may be higher than that of the conventional quantum dot light emitting device. In addition, the light emitting device is formed of the graphene, and thus, flexible light emitting devices of various designs may be realized. Also, lifespan of the graphene quantum dot light emitting device 100 of the present embodiment may be longer than that of the conventional quantum dot light emitting device, since the graphene quantum dots are more durable than quantum dots based on semiconductors.

FIG. 2 is a plan view of a plurality of graphene quantum dots 35 disposed on the first graphene 20. Referring to FIG. 2, the plurality of graphene quantum dots 35 are randomly disposed on the first graphene 20. Distances between the graphene quantum dots 35 in FIG. 2 are exaggerated, and the distance between the graphene quantum dots 35 may be a few nm or less.

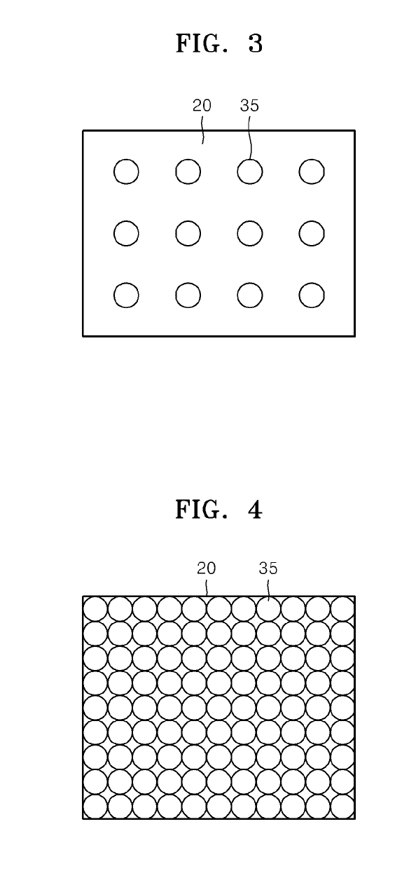

FIG. 3 is a plan view showing a plurality of graphene quantum dots 35 disposed regularly on the first graphene 20. Referring to FIG. 3, the plurality of graphene quantum dots 35 are arranged at predetermined intervals on the first graphene 20. That is, the plurality of graphene quantum dots 35 are separated predetermined interval from each other on the first graphene 20, and thus, arranged regularly.

FIG. 4 is a plan view of a plurality of graphene quantum dots 35 that are regularly arranged on the first graphene 20. Referring to FIG. 4, the plurality of graphene quantum dots 35 are densely arranged on the first graphene 20, without separating from each other. That is, the plurality of graphene quantum dots 35 are arranged on the first graphene 20 while contacting each other. FIGS. 2 through 4 show examples of arranging the plurality of graphene quantum dots 35 on the first graphene 20; however, the present invention is not limited thereto. For example, the graphene quantum dot layer 30 may have a structure in which a plurality of graphene quantum dots 35 are stacked.

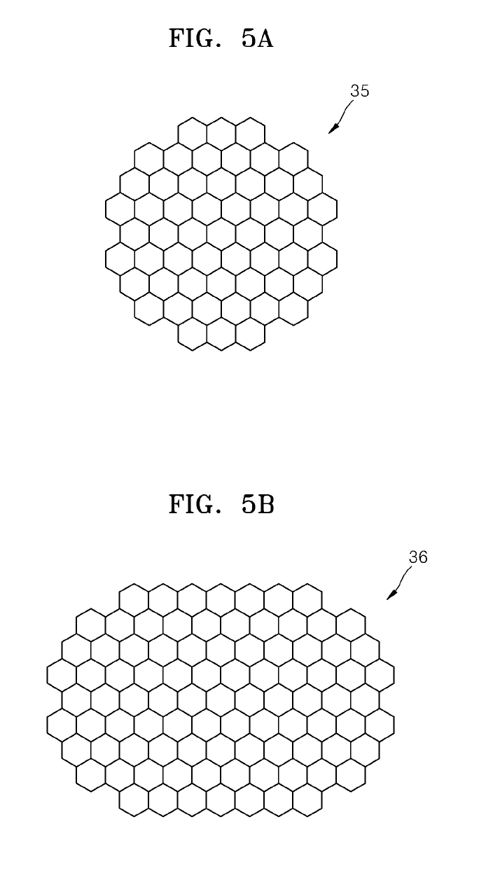

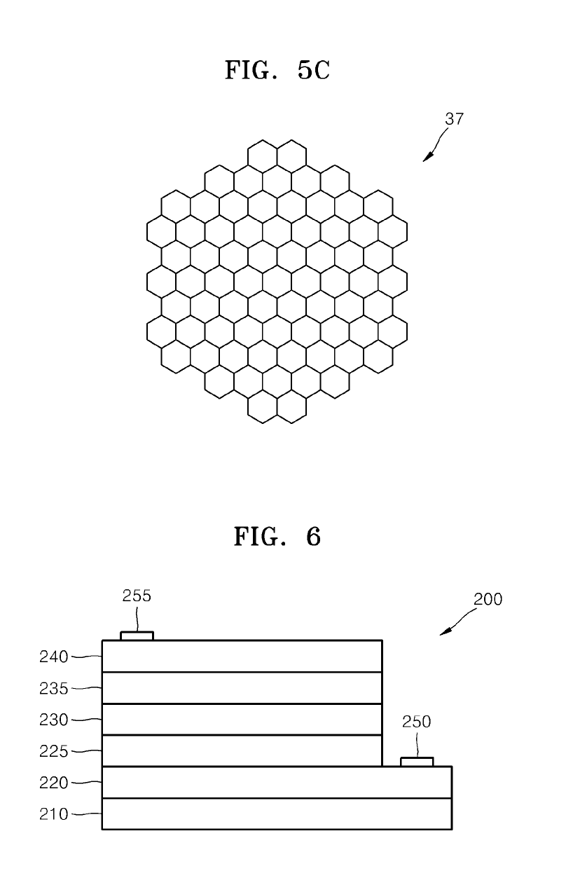

FIGS. 5A through 5C are plan views exemplary showing shapes of the graphene quantum dots 35, 36 or 37.

Referring to FIG. 5A, the graphene quantum dot 35 may be formed as, for example, a circular shape. Referring to FIG. 5B, a graphene quantum dot 36 may be formed as an oval or a mixture of a square and a circle. In addition, as shown in FIG. 5C, a graphene quantum dot 37 may be formed as a hexagonal shape. However, the shape of the graphene quantum dot 35, 36, or 37 is not limited thereto, that is, may be formed as a polygon such as a square, a pentagon, etc. In addition, the graphene quantum dot 35, 36, or 37 may be a nano-particle of the graphene, the shape of which is difficult to be defined.

FIG. 6 is a schematic cross-sectional view of a graphene quantum dot light emitting device 200 according to another embodiment of the present invention.

Referring to FIG. 6, the graphene quantum dot light emitting device 200 of the present embodiment includes a substrate 210, a first graphene 220 disposed on the substrate 210, a graphene quantum dot layer 230 disposed on the first graphene 220, and a second graphene 240 disposed on the graphene quantum dot layer 230. In addition, the graphene quantum dot light emitting device 200 may further include a first charge transport layer 225 disposed between the first graphene 220 and the graphene quantum dot layer 230, and a second charge transport layer 235 disposed between the graphene quantum dot layer 230 and the second graphene 240. In addition, the graphene quantum dot light emitting device 200 may further include a first contact pad 250 that is formed on an exposed portion of the first graphene 220 to be separated from the graphene quantum dot layer 230 and the second graphene 240, and a second contact pad 255 formed on the second graphene 240.

The substrate 210 may be formed of glass, sapphire, or a polymer material such as PET. In addition, the substrate 210 may be formed of Si, ZnO, GaAs, SiC, MgAl₂O₄, MgO, LiAlO₂, LiGaO₂, or GaN. The substrate 210 may be removed after forming the first graphene 220, the first charge transport layer 225, the graphene quantum dot layer 230, the second charge transport layer 235, and the second graphene 240 on the substrate 210. On the other hand, according to the graphene quantum dot light emitting device 200 of the present embodiment, the first graphene 220 may function as a substrate without forming the additional substrate 210.

The first graphene 220 is disposed on the substrate 210. The graphene is a conductive material in which carbon atoms are arranged as a two-dimensional honeycomb shape having a thickness of a layer of atoms. The graphene is stabilized structurally and chemically, and is an excellent conductive material having a charge mobility that is faster than that of silicon. In addition, more electric current may flow on the graphene than copper. In addition, the graphene has a transparency that is higher than that of indium tin oxide (ITO) that is conventionally used as a transparent electrode. The graphene that is not doped with a dopant does not have an energy band gap since a valence band and a conduction band meet each other. However, when a n-type dopant or a p-type dopant is doped on the graphene, energy band gap is generated. The energy band gap may be adjusted according to a kind of the dopant, and doping density.

Here, the first graphene 220 may be n-type graphene. The first graphene 220 may be used as an n-type electrode of the graphene quantum dot light emitting device 200. The n-type graphene 220 is formed by doping at least one graphene sheet with the n-type dopant. That is, the n-type dopant is injected and adsorbed on the graphene sheet to form the n-type graphene 220. The n-type dopant may be, for example, nitrogen (N), fluorine (F), or manganese (Mn); however, the present invention is not limited thereto. The first graphene 220 may have a thickness of about 0.34 nm, and when the first graphene 220 has a structure in which a plurality of graphene sheets are stacked, the thickness of the first graphene 220 may be an interger multiple of about 0.34 nm. Since the thickness of the first graphene 220 is less than a wavelength of light emitted from the graphene quantum dot layer 230, a total reflection may not occur on an interface between the two layers 220 and 230.

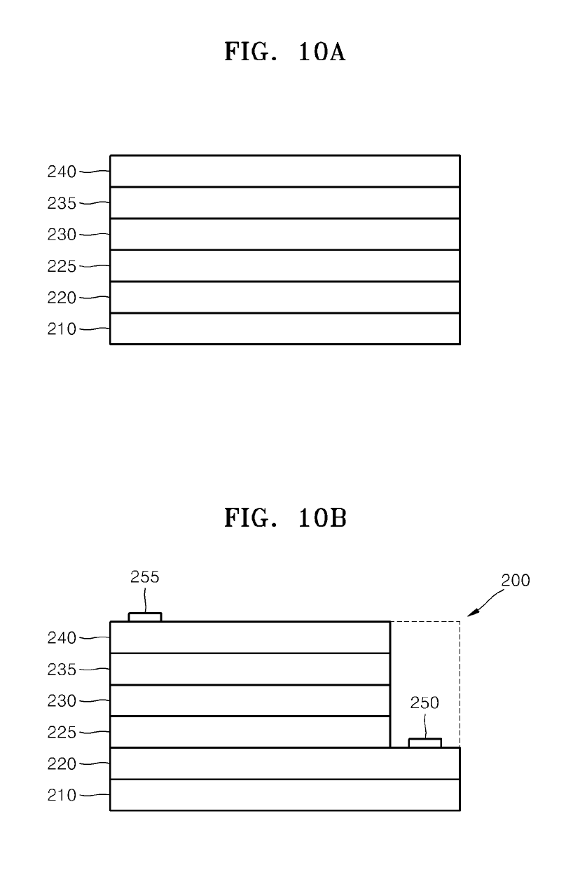

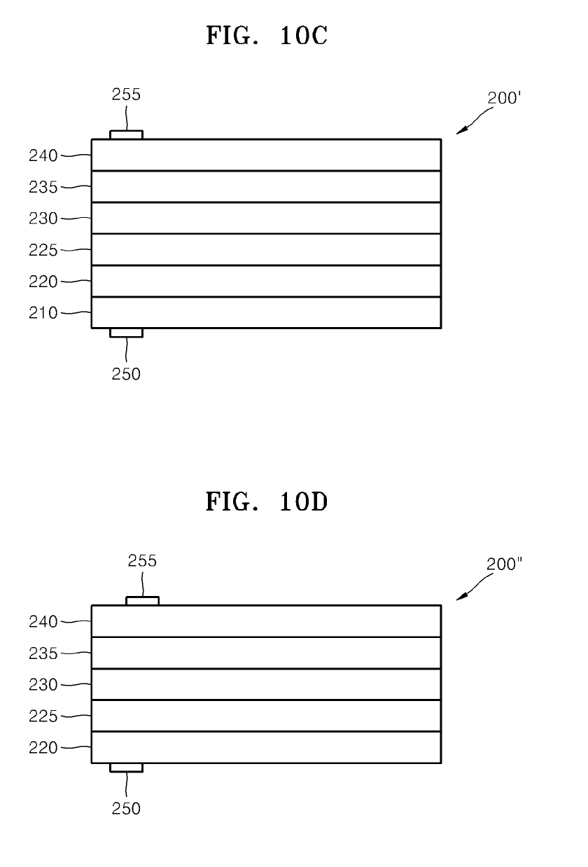

The first contact pad 250 may be disposed on the first graphene 220 to be separated from the first charge transport layer 225, the graphene quantum dot layer 230, the second charge transport layer 235, and the second graphene 240. That is, in a mesa-structure in which a part of the first graphene 220 is exposed due to a mesa-etching of the first charge transport layer 225, the graphene quantum dot layer 230, the second charge transport layer 235, and the second graphene 240, the first contact pad 250 is disposed on the exposed part of the first graphene 220. On the other hand, as shown in FIG. 10C, the first contact pad 250 may be formed on a lower surface of the substrate 210, that is, a surface opposite to the surface there the first graphene 220 is formed, when the substrate 210 is the conductive substrate. Otherwise, as shown in FIG. 10D, the first contact pad 250 may be formed on a lower surface of the first graphene 220, that is, a surface opposite to the surface where the graphene quantum dot layer 230 is formed of the first graphene 220, after removing the substrate 210. In addition, the first contact pad 250 may inject electrons into the first graphene 220 from an external power source.

The first charge transport layer 225 may be disposed on the first graphene 220. When the first graphene 220 is the n-type graphene, the first charge transport layer 225 may be an electron transfer layer(ETL). The first charge transport layer 225 may be formed of, for example, TPBi(1,3,5-tris(N-phenylbenzimidazol-2,yl)benzene), PBD(2-(4-Biphenylyl)-5-(4-tert-butylphenyl)-1,3,4-oxadiazole), BCP(2,9-Dimethyl-4,7-diphenyl-1,10-phenanhro-line), BAlq(Bis-(2-methyl-8-quinolinolate)-4-(phenylphenolato)aluminium), or OXD7(1,3-bis(N,N-t-butyl-phenyl)-1,3,4-oxadiazole). The first charge transport layer 225 may be formed by spin-coating or depositing TPBi on the first graphene 220, for example. In addition, the first charge transport layer 225 formed of the TPBi may be treated by ultraviolet (UV) ray to have a hydrophilic property. As described above, when the first charge transport layer 225 is formed of a polymer material, degradation of the graphene quantum dot light emitting device 200 caused by an oxidation or corrosion may be prevented, and a turn-on voltage may be reduced. An electron injection layer (EIL) may be further disposed between the first graphene 220 and the first charge transport layer 225.

The graphene quantum dot layer 230 may be disposed on the first charge transport layer 225, and may emit light having a predetermined energy level by the recombination between the electrons and holes. The graphene quantum dot layer 230 may include a plurality of graphene quantum dots, which may be arranged on the first charge transport layer 225 in various shapes. Arrangement of the quantum dots are described above with reference to FIGS. 2 through 4. The graphene quantum dot layer 230 may be formed by spin-coating a solution including the plurality of graphene quantum dots onto the first charge transport layer 225 and drying the solution by using a thermal process. In addition, the solution may include an organic solvent, for example, polyethylene oxide (PEO) or poly(ethylene succinate) (PES).

The graphene quantum dot may be a graphen nano-particle having a size of about 1 nm to about 30 nm, or about 1 nm to about 20 nm, in more detail, about 1 nm to about 10 nm. In addition, a functional group may be further coupled to a surface or an edge of the graphene quantum dot. Amine-based functional group may be attached to the graphene quantum dot, for example, alkylamines, aniline, or polyethylene glycol (PEG). Characteristics of the graphene quantum dot are described above.

The second charge transport layer 235 may be disposed on the graphene quantum dot layer 230. The second charge transport layer 235 may be a hole transfer layer (HTL), when the second graphene 240 is the p-type graphene. The second charge transport layer 235 may be formed of, for example, poly-TPD(N,N′-bis(3-methylphenyl)-N,N′-bis(phenyl)-benzidine), PEDOT(poly(3,4-ethylenedioxythiophene)), PSS(poly(styrenesulfonate)), PPV(poly(p-phenylene vinylene)), PVK(poly(N-vinylcarbazole)), TFB(poly[(9,9-dioctylfluorenyl-2,7-diyl)-co-(4,4′(N-(4-sec-butylphenyl)))diphenylamine]), PFB, TBADN(3-Tert-butyl-9,10-di(naphth-2-yl)anthracene), NPB(N,N′-bis(1-naphtalenyl)-N-N′-bis(phenyl-benzidine)), Spiro-NPB(N,N′-di(naphthalen-1-yl)-N,N′-diphenyl-spiro), DMFL-NPB(N,N′-di(naphthalene-1-yl)-N,N′-diphenyl-9,9′-dimethyl-fluorene), DPFL-NPB(N,N′-di(naphthalen-1-yl)-N,N′-diphenyl-9,9′-diphenyl-fluorene), or mHOST5(2,7-Di(N,N′-carbarzolyl)-9,9-bis[4-(2-ethylhexyloxy)-phenyl]fluorine). The second charge transport layer 235 may be formed of a wet-coating method such as the spin coating method. For example, the second charge transport layer 235 may be formed by spin-coating or depositing poly-TPD on the graphene quantum dot layer 230, and annealing the poly-TPD at a temperature of about 100° C. to about 200° C., for example, at a temperature of about 120° C. In addition, the second charge transport layer 235 may be treated by the UV ray to have the hydrophilic property. As described above, if the second charge transport layer 235 is formed of the polymer material, the polymer material is highly resistant against harmful material such as oxygen or moisture, and thus, lifespan of the graphene quantum dot light emitting device 200 may be increased. In addition, a turn-on voltage, that is, an operation initiating voltage, of the graphene quantum dot light emitting device 200 may be reduced. On the other hand, a hole injection layer (HIL) (not shown) may be further disposed between the second graphene 240 and the second charge transport layer 235.

The second graphene 240 may be disposed on the second charge transport layer 235. Here, the second graphene 240 may be the p-type graphene. The second graphene 240 may be used as a p-type electrode of the graphene quantum dot light emitting device 200. The p-type graphene 240 is formed by doping at least one graphene sheet with the p-type dopant. That is, the p-type dopant is injected and adsorbed on the graphene sheet to form the p-type graphene 240. The p-type dopant may be, for example, oxygen (O), gold (Au), or bismuth (Bi); however, the present invention is not limited thereto. On the other hand, the second graphene 240 may have a thickness of about 0.34 nm, and may have a structure in which a plurality of graphene sheets are stacked. Since the thickness of the second graphene 240 is less than a wavelength of light emitted from the graphene quantum dot layer 230, a total reflection may not occur on an interface between the two layers 230 and 240.

The second contact pad 255 may be disposed on the second graphene 240.

The second contact pad 255 may inject holes in the second graphene 240. In the above description, the first and second graphenes 220 and 240 are respectively the n-type and p-type graphenes; however, the first and second graphenes 220 and 240 may be respectively p-type and n-type graphenes. Also, the first and second charge transport layers 225 and 235 are respectively ETL and HTL; however, the first and second charge transport layer 225 and 235 may be respectively HTL and ETL.

According to the graphene quantum dot light emitting device 200 of the present embodiment, the light emitting efficiency may be higher than that of the conventional quantum dot light emitting device. In addition, the light emitting device is formed of the graphene, and thus, flexible light emitting devices of various designs may be realized. Also, lifespan of the graphene quantum dot light emitting device 200 of the present embodiment may be longer than that of the conventional quantum dot light emitting device, since the graphene quantum dots are more durable than the quantum dots based on semiconductors.

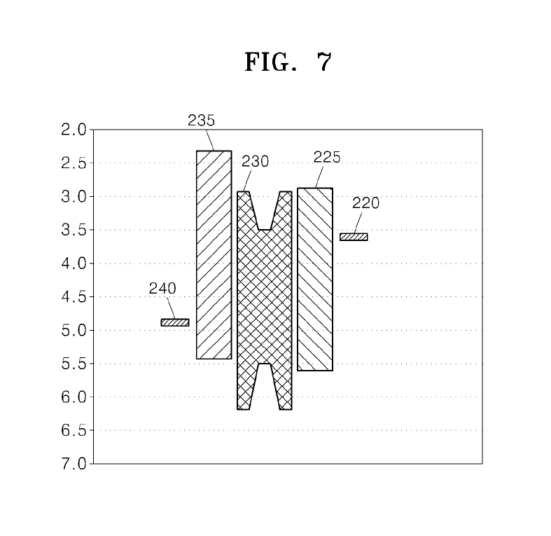

FIG. 7 shows an example of an energy band structure of the graphene quantum dot light emitting device 200 shown in FIG. 6. The energy band structure shown in FIG. 7 is the energy band structure of the graphene quantum dot light emitting device 200 including the ETL 225 formed of TPBi, the graphene quantum dot layer 230, the HTL 235 formed of poly-TPD, and the p-type graphene 240 that are stacked sequentially on the n-type graphene 220.

Referring to FIG. 7, a highest occupied molecular level (HOMO) energy band level of the HTL 235 is about 5.4 eV, and a valence band level of the graphene quantum dot layer 230 is about 6.2 eV. When a difference between the energy band levels of the HTL 235 and the graphene quantum dot layer 230, that is, a band offset, is large, the light emitting efficiency of the light emitting device may be degraded. The band offset may increase the turn-on voltage and may reduce an electric power efficiency caused by the increase of the operating voltage, as well as the increase of the light emitting efficiency. Therefore, in order to improve performances of the graphene quantum dot light emitting device 200, the band offset between the graphene quantum dot layer 230 and the HTL 235 needs to be reduced. That is, as shown in FIG. 7, the energy band level of the graphene quantum dot layer 230 needs to be reduced. The graphene quantum dot light emitting device 200 of the present embodiment may reduce the band gap of the graphene quantum dot layer 230 by adjusting the size and shape of the graphene quantum dots. Therefore, the light emitting efficiency of the graphene quantum dot light emitting device 200 may be improved.

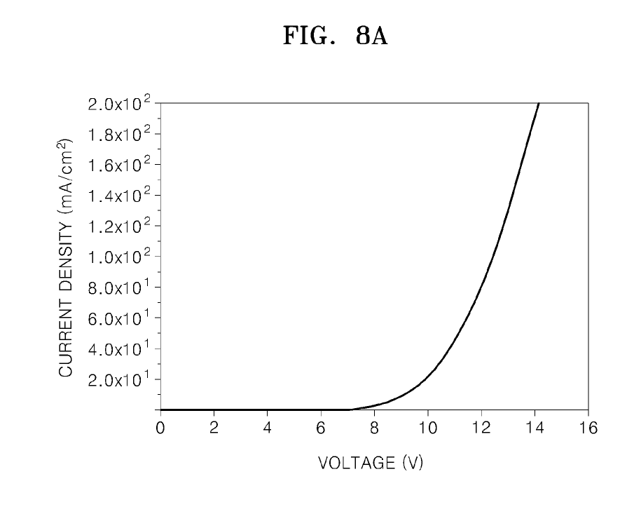

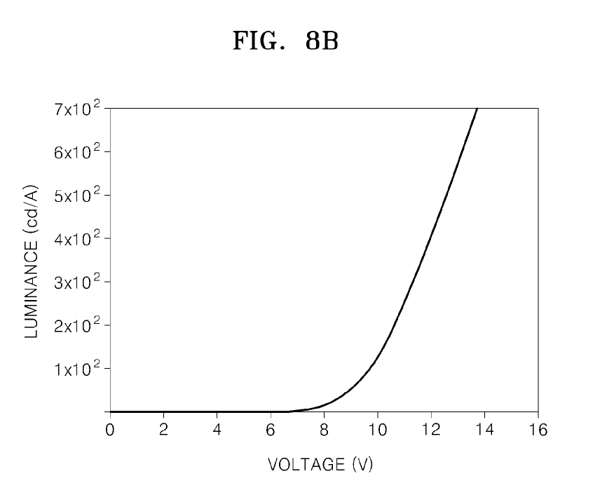

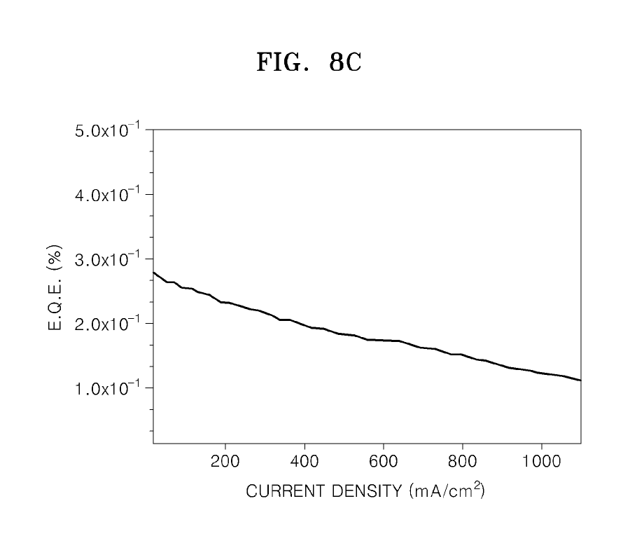

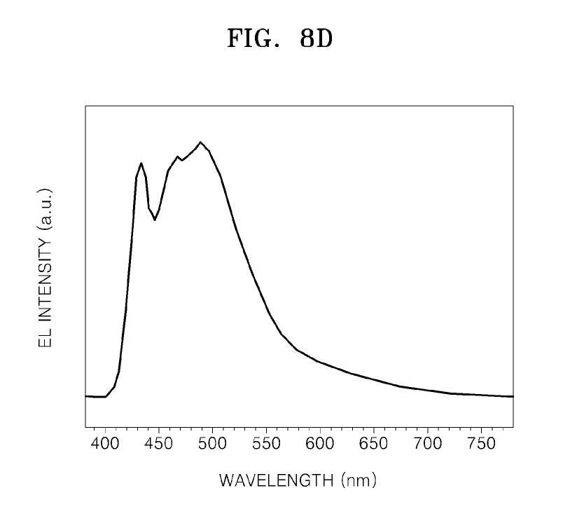

FIGS. 8A through 8D schematically show the light emitting characteristics of the graphene quantum dot light emitting device 200 of FIG. 6.

Referring to FIG. 8A, as a magnitude of the voltage applied to the graphene quantum dot light emitting device 200, a current density of the graphene quantum dot light emitting device 200 increases. Also, the current density is sharply increased from when a voltage of about 10 V is applied to the graphene quantum dot light emitting device 200, which means the turn-on voltage of the graphene quantum dot light emitting device 200 is about 10 V.

Referring to FIG. 8B, as the magnitude of the voltage applied to the graphene quantum dot light emitting device 200, luminance of the graphene quantum dot light emitting device 200 also increases. In addition, the luminance is sharply increased from when the voltage of about 10 V is applied to the graphene quantum dot light emitting device 200, which represents that the turn-on voltage of the graphene quantum dot light emitting device 200 is about 10 V.

FIG. 8C shows an external quantum efficiency (E.Q.E.) with respect to the current density of the graphene quantum dot light emitting device 200. Referring to FIG. 8C, the E.Q.E. of the graphene quantum dot light emitting device 200 is about 0.3%.

FIG. 8D shows an electroluminescence (EL) intensity (arbitrary unit, a.u.) with respect to a wavelength of the light emitted from the graphene quantum dot light emitting device 200. Referring to FIG. 8D, the graphene quantum dot light emitting device 200 shows sky-blue light emitting characteristics, and has a relatively wide half-width.

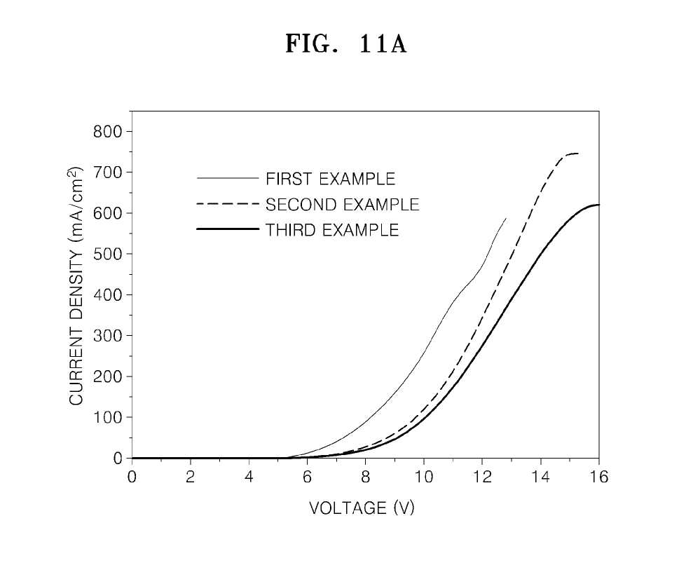

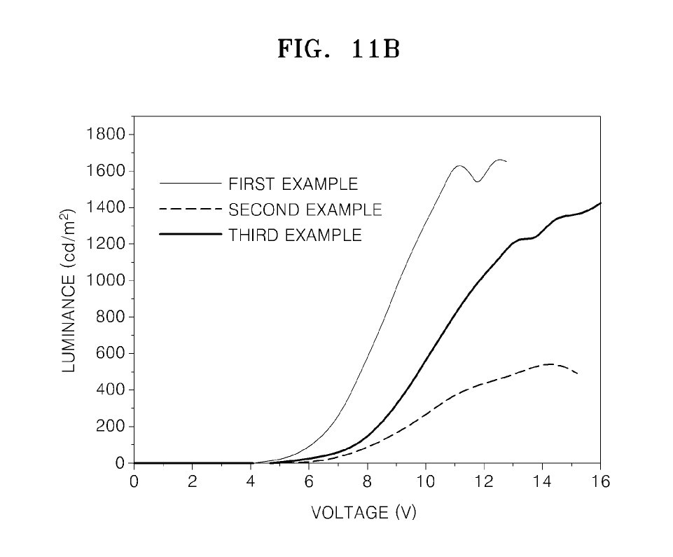

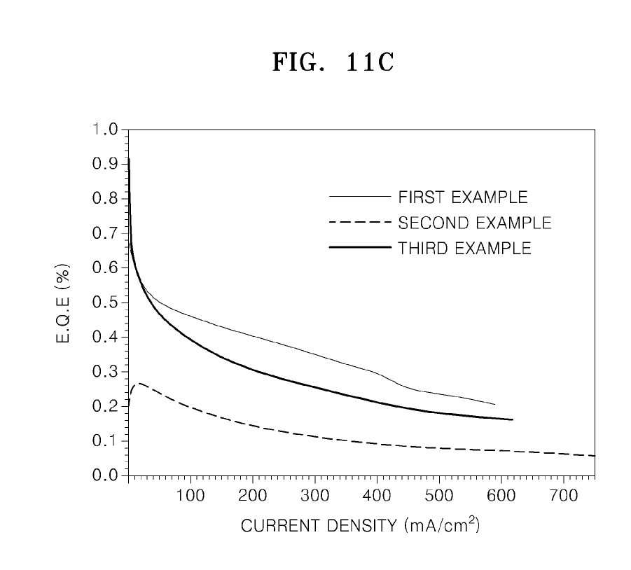

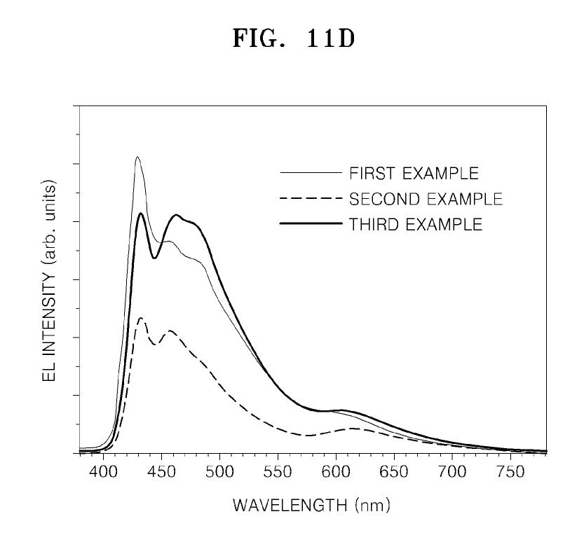

FIGS. 11A through 11D are graphs schematically showing light emitting characteristics of graphene quantum dot light emitting device according to first, second and third examples. Here, the graphene quantum dot light emitting devices according to the first, second and third examples include a HTL formed of poly-TPD. The graphene quantum dot layer of the first example include a plurality of graphene quantum dots, the graphene quantum dot layer of the second example include a plurality of graphene quantum dots and about 40,000 molecular weight of PEO, and the graphene quantum dot layer of the third example include a plurality of graphene quantum dots and about 500,000 molecular weight of PEO.

Referring to FIG. 11A, as magnitudes of the voltages applied to the graphene quantum dot light emitting devices of the first, second, and third examples increase, a current density in each of the graphene quantum dot light emitting devices according to the first through third examples increases. Increasing rates of the current densities in the graphene quantum dot light emitting devices according to the first through third examples are different from each other because amounts of PEO included in the graphene quantum dot layers are different from each other.

Referring to FIG. 11 B, as magnitudes of the voltages applied to the graphene quantum dot light emitting devices of the first, second, and third examples increase, luminance of each of the graphene quantum dot light emitting devices also increases. Increasing rates of the luminances in the graphene quantum dot light emitting devices according to the first through third examples are different from each other because amounts of PEO included in the graphene quantum dot layers are different from each other.

FIG. 11C shows E.Q.E. with respect to the current densities in the graphene quantum dot light emitting devices according to the first, second, and third examples. Referring to FIG. 11C, the E.Q.E. may be changed according to the amount of PEO included in the graphene quantum dot layer.

FIG. 11D shows an EL intensity (arbitrary unit, a.u.) with respect to a wavelength of the light emitted from the graphene quantum dot light emitting devices according to the first, second, and third examples. Referring to FIG. 11D, the graphene quantum dot light emitting devices of the first through third examples show sky-blue light emitting characteristics, and have relatively wide half-widths. The EL intensities of the graphene quantum dot light emitting devices of the first through third examples may be different from each other according to the amounts of PEO included in the graphene quantum dot layers.

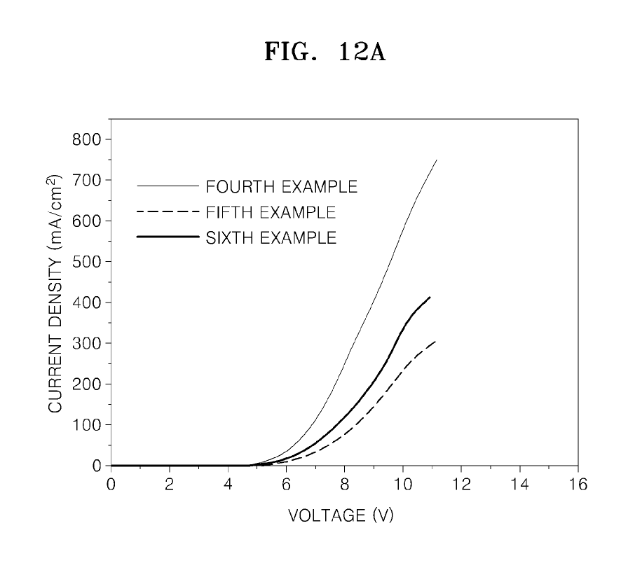

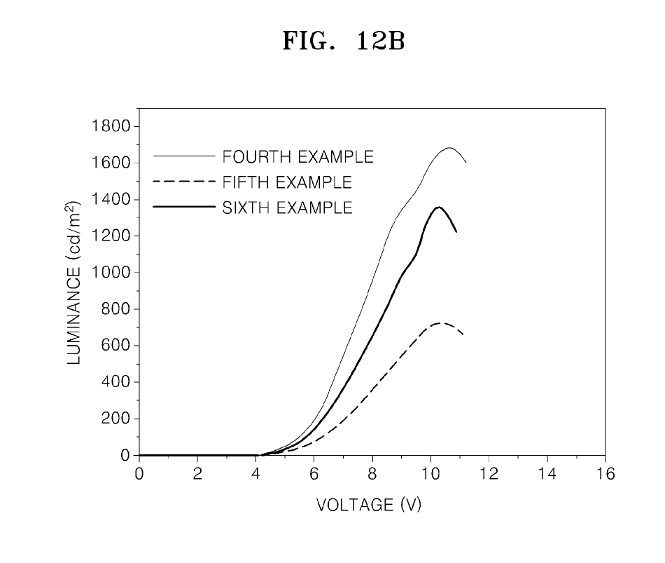

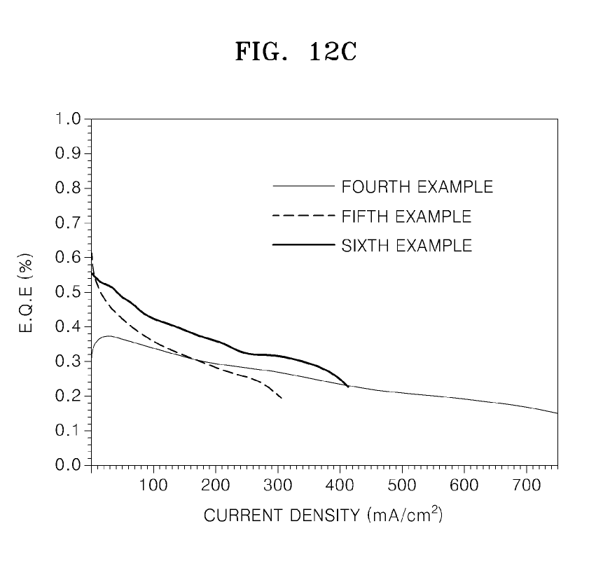

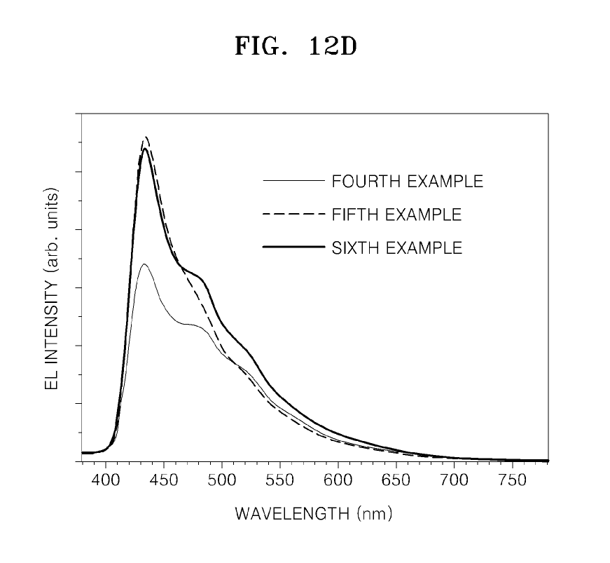

FIGS. 12A through 12D are graphs schematically showing light emitting characteristics of graphene quantum dot light emitting devices according to fourth, fifth, and sixth examples. Here, the graphene quantum dot light emitting devices according to fourth, fifth, and sixth examples include an HTL formed of TFB. The graphene quantum dot layer of the fourth example includes a plurality of graphene quantum dots, the graphene quantum dot layer of the fifth example include a plurality of graphene quantum dots and about 40,000 molecular weight of PEO, and the graphene quantum dot layer of the sixth example include a plurality of graphene quantum dots and about 500,000 molecular weight of PEO.

Referring to FIG. 12A, as magnitudes of the voltages applied to the graphene quantum dot light emitting devices of the fourth through sixth examples increase, a current density in each of the graphene quantum dot light emitting devices according to the fourth through sixth examples increases. Increasing rates of the current densities in the graphene quantum dot light emitting devices according to the fourth through sixth examples are different from each other because amounts of PEO included in the graphene quantum dot layers are different from each other.

Referring to FIG. 12B, as magnitudes of the voltages applied to the graphene quantum dot light emitting devices of the fourth through sixth examples increase, luminance of each of the graphene quantum dot light emitting devices also increases. Increasing rates of the luminances in the graphene quantum dot light emitting devices according to the fourth through sixth examples are different from each other because amounts of PEO included in the graphene quantum dot layers are different from each other.

FIG. 12C shows E.Q.E. with respect to the current densities in the graphene quantum dot light emitting devices according to the fourth through sixth examples. Referring to FIG. 12C, the E.Q.E. may be changed according to the amount of PEO included in the graphene quantum dot layer.

FIG. 12D shows EL intensities (arbitrary unit, a.u.) with respect to wavelengths of the light emitted from the graphene quantum dot light emitting devices according to the fourth through sixth examples. Referring to FIG. 12D, the graphene quantum dot light emitting devices of the fourth through sixth examples show sky-blue light emitting characteristics, and have relatively wide half-widths. The EL intensities of the graphene quantum dot light emitting devices of the first through third examples may be different from each other according to the amounts of PEO included in the graphene quantum dot layers. Thus, light emitting characteristics of graphene quantum dot light emitting device according to an embodiment of the present invention may also be adjusted by controlling the amount of organic solvent such as PEO and PED, included in the graphene quantum dot layer.

Next, a method of manufacturing the graphene quantum dot light emitting device 100 or 200 according to an embodiment of the present invention will be described as follows.

FIGS. 9A through 9F are cross-sectional views illustrating processes of manufacturing the graphene quantum dot light emitting device 100 according to an embodiment of the present invention.

Referring to FIG. 9A, the first graphene 20 is formed on the substrate 10. At least one graphene sheet may be formed on the substrate 10 by using the CVD method, the mechanical or chemical removal method, or the epitaxy growth method. In addition, the graphene sheet is doped with a first dopant. Here, the first dopant may be the n-type dopant, and may include, for example, N, F, or Mn. However, the present invention is not limited thereto. The n-type dopant is injected on the graphene sheet and adsorbed on the graphene sheet to form the n-type graphene 20. On the other hand, the substrate 10 may be removed after forming the first graphene 20, the graphene quantum dot layer 30, and the second graphene 40 thereon. Otherwise, according to the method of manufacturing the graphene quantum dot light emitting device 100 of the present embodiment, the first graphene 20 may be used as the substrate without forming the substrate 10 separately.

Next, referring to FIG. 9B, the graphene quantum dot layer 30 may be formed on the first graphene 20. The graphene quantum dot layer 30 may be formed by spin-coating the plurality of graphene quantum dots on the first graphene 20. The graphene quantum dots may be formed by applying ultrasonic waves to a solution including graphene or graphite, and breaking the graphene or the graphite into a plurality of nano-particles.

On the other hand, the graphene quantum dot layer 30 may be formed by forming the graphene on the first graphene 20 by using the CVD method, the mechanical or chemical removal method, or the epitaxy growth method, and applying plasma shock to the graphene so that the graphene may be broken into nano-particles.

In addition, the graphene quantum dots may be formed by heating graphene oxide or graphite oxide to reduce the graphene oxide or the graphite oxide, and cutting the reduced portion of the graphene oxide or the graphite oxide. Here, the oxidation and reduction processes of the graphene or the graphite may be performed twice or more repeatedly, and thus, the size and shape of the graphene quantum dot may be adjusted. In addition, van der Waals force at the graphene or the graphite may be reduced through the oxidation and reduction processes of the graphene or the graphite. The graphene quantum dot may have a size of about 1 nm to about 30 nm, or about 1 nm to about 20 nm, in more detail, about 1 nm to about 10 nm. The graphene quantum dots of desired size may be filtered by a dialysis. On the other hand, as described above, a functional group may be further coupled to a surface or an edge of the graphene quantum dot. Amine-based functional group may be attached to the graphene quantum dot, for example, alkylamines, aniline, or polyethylene glycol (PEG). Characteristics of the graphene quantum dot are described above.

Referring to FIG. 9C, the second graphene 40 is formed on the graphene quantum dot layer 30. At least one graphene sheet is formed on the graphene quantum dot layer 30 by the CVD method, the mechanical or chemical removal method, or the epitaxy growth method. In addition, the graphene sheet is doped with a second dopant. Here, the second dopant may be the p-type dopant, and may include, for example, O, Au, or Bi. However, the present invention is not limited thereto. The p-type dopant is injected and adsorbed on the graphene sheet to form the p-type graphene 40. According to the above description, the first and second graphenes 20 and 40 may be the n-type and the p-type graphenes; however, the first and second graphenes 20 and 40 may be the p-type and the n-type graphenes.

Referring to FIG. 9D, the first and second contact pads 50 and 55 are formed. The first contact pad 50 is formed on the first graphene 20 to be separated from the graphene quantum dot layer 30 and the second graphene 40. That is, the first contact pad 50 may be formed on an exposed portion of the first graphene 20 after performing a mesa-etching of the graphene quantum dot layer 30 and the second graphene 40. In addition, the second contact pad 55 may be formed on the second graphene 40. According to the method of manufacturing the graphene quantum dot light emitting device 100, a general CVD equipment may be used instead of a metal-organic chemical vapor deposition (MOCVD) equipment that is expensive, and thus, fabrication costs may be reduced and the processing time may be reduced.

On the other hand, the first and second contact pads 50 and 55 shown in FIG. 9D may be formed as follows. Referring to FIG. 9E, the first contact pad 50 may be formed on the lower surface of the substrate 10, that is, the surface facing the other surface on which the first graphene 20 is formed, when the substrate 10 is the conductive substrate. In addition, the second contact pad 55 may be formed on the second graphene 40.

In addition, referring to FIG. 9F, the first contact pad 50 may be formed on the lower surface of the first graphene 20, that is, the surface facing the other surface on which the graphene quantum dot layer 30 is formed, after removing the substrate 10. In addition, the second contact pad 55 may be formed on the second graphene 40.

FIGS. 10A through 10F are cross-sectional views illustrating processes of manufacturing the graphene quantum dot light emitting device 200 according to another embodiment of the present invention.

Referring to FIG. 10A, the first graphene 220, the first charge transport layer 225, the graphene quantum dot layer 230, the second charge transport layer 235, and the second graphene 240 may be formed sequentially on the substrate 210.

The first graphene 220 is formed on the substrate 210. At least one graphene sheet may be formed on the substrate 210 by using the CVD method, the mechanical or chemical removal method, or the epitaxy growth method. In addition, the graphene sheet is doped with a first dopant. Here, the first dopant may be the n-type dopant, and may include, for example, N, F, or Mn. Therefore, the first graphene 220 may be the n-type graphene 220. On the other hand, the substrate 210 may be removed after forming the first graphene 220, the first charge transport layer 225, the graphene quantum dot layer 230, the second charge transport layer 235, and the second graphene 240 thereon. Otherwise, according to the method of manufacturing the graphene quantum dot light emitting device 200 of the present embodiment, the first graphene 220 may be used as the substrate without forming the substrate 210 separately. After forming the first graphene 220, the first graphene 220 may be dried in a nitrogen oven.

Next, the first charge transport layer 225 may be formed on the first graphene 220. The first charge transport layer 225 may be an ETL. The first charge transport layer 225 may be formed by spin-coating or depositing the TPBi, PBD, BCP, BAlq, or OXD7 on the first graphene 220. The first charge transport layer 225 may be annealed to be dried or hardened. In addition, the first charge transport layer 225 is processed by the UV rays to improve the hydrophilic property on a surface thereof. Therefore, the solution including the graphene quantum dots may be easily deposited on the surface of the first charge transport layer 225.

In addition, the graphene quantum dot layer 230 may be formed on the first charge transport layer 225. The graphene quantum dot layer 230 may be formed by spin coating the first charge transport layer 225 with the solution including the plurality of graphene quantum dots. In addition, the solution may further include an organic solvent, for example, PEO or PES.

The graphene quantum dots may be formed by applying ultrasonic waves to a solution including graphene or graphite, and breaking the graphene or the graphite into a plurality of nano-particles. On the other hand, the graphene quantum dot layer 230 may be applying plasma shock to the graphene sheet, and breaking the graphene sheet into nano-particles after forming the graphene sheet on the first graphene 220.

In addition, the graphene quantum dots may be formed by heating graphene oxide or graphite oxide to reduce the graphene oxide or the graphite oxide, and cutting the reduced portion of the graphene oxide or the graphite oxide. Here, the oxidation and reduction processes of the graphene or the graphite may be repeatedly performed twice or more, and thus, the size and shape of the graphene quantum dot may be adjusted. In addition, van der Waals force at the graphene or the graphite may be reduced through the oxidation and reduction processes of the graphene or the graphite. The graphene quantum dot may have a size of about 1 nm to about 30 nm, or about 1 nm to about 20 nm, in more detail, about 1 nm to about 10 nm. The graphene quantum dots of desired size may be filtered by a dialysis. On the other hand, as described above, a functional group may be further coupled to a surface or an edge of the graphene quantum dot. Amine-based functional group may be attached to the graphene quantum dot, for example, alkylamines, aniline, or polyethylene glycol (PEG).

The second charge transport layer 235 may be formed on the graphene quantum dot layer 230. The second charge transport layer 235 may be an HTL. The second charge transport layer 235 may be formed by spin coating or depositing poly-TPD, PEDOT, PSS, PPV, PVK, TFB, PFB, TBADN, NPB, Spiro-NPB, DMFL-NPB, DPFL-NPB, or mHOST5 on the graphene quantum dot layer 230. The second charge transport layer 235 may be annealed to be dried or hardened. In addition, the second charge transport layer 235 may be processed by the UV ray so as to improve the hydrophilic property on the surface thereof. Therefore, the solution including the graphene quantum dots may be easily deposited on the surface of the second charge transport layer 235.

The second graphene 240 may be formed on the second charge transport layer 235. At least one graphene sheet is formed on second charge transport layer 235, and the graphene sheet is doped with the second dopant to form the second graphene 240. After forming the second graphene 240, the second graphene 240 may be heated in a nitrogen oven to be dried. Here, the second dopant may be the p-type dopant, and may include, for example, O, Au, or Bi. According to the above description, the first and second graphenes 220 and 240 may be the n-type and the p-type graphenes; however, the first and second graphenes 220 and 240 may be the p-type and the n-type graphenes.

Referring to FIG. 10B, the first and second contact pads 250 and 255 are formed. The first contact pad 250 may be formed on the first graphene 220 to be separated from the first charge transport layer 225, the graphene quantum dot layer 230, the second charge transport layer 235, and the second graphene 240. That is, the first contact pad 250 may be formed on an exposed portion of the first graphene 220 after performing a mesa-etching of the first charge transport layer 225, the graphene quantum dot layer 230, the second charge transport layer 235, and the second graphene 240. In addition, the second contact pad 255 may be formed on the second graphene 240. According to the method of manufacturing the graphene quantum dot light emitting device 200, a general CVD equipment may be used instead of a metal-organic chemical vapor deposition (MOCVD) equipment that is expensive, and thus, fabrication costs may be reduced and the processing time may be reduced.

On the other hand, the first and second contact pads 250 and 255 shown in FIG. 10D may be formed as follows. Referring to FIG. 10C, the first contact pad 250 may be formed on the lower surface of the substrate 210, that is, the surface facing the other surface on which the first graphene 220 is formed, when the substrate 210 is the conductive substrate. In addition, referring to FIG. 10D, the first contact pad 250 may be formed on the lower surface of the first graphene 220, that is, the surface facing the other surface on which the first charge transport layer 225 is formed, after removing the substrate 210.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A graphene quantum dot light emitting device comprising:
a first graphene;
a graphene quantum dot layer disposed on the first graphene and comprising a plurality of graphene quantum dots; and
a second graphene disposed on the graphene quantum dot layer.

2. The graphene quantum dot light emitting device of claim 1, wherein the first graphene is an n-type graphene, and the second graphene is a p-type graphene.

3. The graphene quantum dot light emitting device of claim 2, further comprising an electron transport layer (ETL) disposed between the n-type graphene and the graphene quantum dot layer.

4. The graphene quantum dot light emitting device of claim 3, wherein the ETL comprises TPBi(1,3,5-tris(N-phenylbenzimidazol-2,yl)benzene), PBD(2-(4-Biphenylyl)-5-(4-tert-butylphenyl)-1,3,4-oxadiazole), BCP(2,9-Dimethyl-4,7-diphenyl-1,10-phenanhro-line), BAlq(Bis-(2-methyl-8-quinolinolate)-4-(phenylphenolato)aluminium), or OXD7(1,3-bis(N,N-t-butyl-phenyl)-1,3,4-oxadiazole).

5. The graphene quantum dot light emitting device of claim 2, further comprising a hole transport layer (HTL) between the graphene quantum dot layer and the p-type graphene.

6. The graphene quantum dot light emitting device of claim 5, wherein the HTL comprises poly-TPD(N,N′-bis(3-methylphenyl)-N,N′-bis(phenyl)-benzidine), PEDOT(poly(3,4-ethylenedioxythiophene)), PSS(poly(styrenesulfonate)), PPV(poly(p-phenylene vinylene)), PVK(poly(N-vinylcarbazole)), TFB(poly[(9,9-dioctylfluorenyl-2,7-diyl)-co-(4,4′(N-(4-sec-butylphenyl)))diphenylamine]), PFB, TBADN(3-Tert-butyl-9,10-di(naphth-2-yl)anthracene), NPB(N,N′-bis(1-naphtalenyl)-N-N′-bis(phenyl-benzidine)), Spiro-NPB(N,N′-di(naphthalen-1-yl)-N,N′-diphenyl-spiro), DMFL-NPB(N,N′-di(naphthalene-1-yl)-N,N′-diphenyl-9,9′-dimethyl-fluorene), DPFL-NPB(N,N′-di(naphthalen-1-yl)-N,N′-diphenyl-9,9′-diphenyl-fluorene), or mHOST5(2,7-Di(N,N′-carbarzolyl)-9,9-bis[4-(2-ethylhexyloxy)-phenyl]fluorine).

7. The graphene quantum dot light emitting device of claim 1, wherein the graphene quantum dot layer further comprises an organic solvent.

8. The graphene quantum dot light emitting device of claim 1, wherein the plurality of graphene quantum dots have a size of about 1 nm to about 30 nm.

9. The graphene quantum dot light emitting device of claim 2, wherein the n-type graphene is doped with one of selected from nitrogen (N), fluorine (F), and manganese (Mn).

10. The graphene quantum dot light emitting device of claim 2, wherein the p-type graphene is doped with one of selected from oxygen (O), gold (Au), and bismuth (Bi).

11. The graphene quantum dot light emitting device of claim 1, further comprising a first contact pad that is disposed on the first graphene to be separated from the graphene quantum dot layer and the second graphene, or on a lower surface of the first graphene.

12. The graphene quantum dot light emitting device of claim 1, further comprising a second contact pad disposed on the second graphene.

13. A method of manufacturing a graphene quantum dot light emitting device, the method comprising:
forming a first graphene doped with a first dopant;
forming a graphene quantum dot layer comprising a plurality of graphene quantum dots on the first graphene; and
forming a second graphene doped with a second dopant on the graphene quantum dot layer.

14. The method of claim 13, wherein the first dopant is an n-type dopant, and the second dopant is a p-type dopant.

15. The method of claim 14, wherein the n-type dopant is one of selected from nitrogen (N), fluorine (F), and manganese (Mn).

16. The method of claim 14, wherein the p-type dopant is one of selected from oxygen (O), gold (Au), and bismuth (Bi).

17. The method of claim 14, further comprising forming an electron transport layer (ETL) between the first graphene and the graphene quantum dot layer.

18. The method of claim 17, wherein the ETL comprises TPBi(1,3,5-tris(N-phenylbenzimidazol-2,yl)benzene), PBD(2-(4-Biphenylyl)-5-(4-tert-butylphenyl)-1,3,4-oxadiazole), BCP(2,9-Dimethyl-4,7-diphenyl-1,10-phenanhro-line), BAlq(Bis-(2-methyl-8-quinolnolate)-4-(phenylphenolato)aluminium), or OXD7(1,3-bis(N,N-t-butyl-phenyl)-1,3,4-oxadiazole).

19. The method of claim 14, further comprising forming a hole transport layer (HTL) between the graphene quantum dot layer and the second graphene.

20. The method of claim 19, wherein the HTL comprises poly-TPD(N,N′-bis(3-methylphenyl)-N,N′-bis(phenyl)-benzidine), PEDOT(poly(3,4-ethylenedioxythiophene)), PSS(poly(styrenesulfonate)), PPV(poly(p-phenylene vinylene)), PVK(poly(N-vinylcarbazole)), TFB(poly[(9,9-dioctylfluorenyl-2,7-diyl)-co-(4,4′(N-(4-sec-butylphenyl)))diphenylamine]), PFB, TBADN(3-Tert-butyl-9,10-di(naphth-2-yl)anthracene), NPB(N,N′-bis(1-naphtalenyl)-N-N′-bis(phenyl-benzidine)), Spiro-NPB (N,N′-di(naphthalen-1-yl)-N,N′-diphenyl-spiro), DMFL-NPB(N,N′-di(naphthalene-1-yl)-N,N′-diphenyl-9,9′-dimethyl-fluorene), DPFL-NPB(N,N′-di(naphthalen-1-yl)-N,N′-diphenyl-9,9′-diphenyl-fluorene), or mHOST5(2,7-Di(N,N′-carbarzolyl)-9,9-bis[4-(2-ethylhexyloxy)-phenyl]fluorine).

21. The method of claim 13, wherein the plurality of graphene quantum dots are formed by applying ultrasonic waves to a solution including graphite, and breaking the graphite.

22. The method of claim 13, wherein the plurality of graphene quantum dots are formed by heating graphite oxide to reduce a part of the graphite oxide, and cutting the reduced part of the graphite oxide.

23. The method of claim 13, wherein the graphene quantum dot layer is formed by spin coating the plurality of graphene quantum dots on the first graphene.
